(19) United States
(12) Patent Application Publication
(10) Pub. No.: US 2025/0331422 A1
(43) Pub. Date: Oct. 23, 2025

(54) FLEXIBLE THERMOELECTRIC DEVICE MODULE AND MANUFACTURING METHOD THEREFOR

(71) Applicant: KOREA ELECTROTECHNOLOGY RESEARCH INSTITUTE, Changwon-si (KR)

(72) Inventors: Hyekyoung CHOI, Changwon-si (KR); Seung Il CHA, Changwon-si (KR); Min Ju YUN, Changwon-si (KR)

(21) Appl. No.: 19/203,172

(22) Filed: May 9, 2025

Related U.S. Application Data
(63) Continuation of application No. PCT/KR2022/020232, filed on Dec. 13, 2022.

(30) Foreign Application Priority Data
Nov. 9, 2022 (KR) 10-2022-0148463

(51) Int. Cl. H10N 10/82; H10N 10/01

(52) U.S. Cl. CPC H10N 10/82; H10N 10/01

(57) ABSTRACT

Proposed are a flexible thermoelectric device module and a manufacturing method therefor. The flexible thermoelectric device module, which is an energy conversion device utilizing the voltage generated due to the temperature difference between both ends of the device, improves heat-to-electricity conversion efficiency while ensuring flexibility and mechanical safety. The module includes at least one or more n-type and p-type thermal legs, a conductor for electrically connecting the thermal legs, and an insulation means surrounding the thermal legs, wherein the insulation means is formed with an insulating resin-based material including a partial air gap. The module more tightly adheres to a low-temperature heat source such as the human body so as to enable the effective securing of a large temperature difference and thus has the advantage of enabling the provision of more enhanced energy harvesting performance.

### REFERENCE TO RELATED APPLICATIONS

This is a continuation of International Patent Application PCT/KR2022/020232 filed on Dec. 13, 2022, which designates the United States and claims priority of Korean Patent Application No. 10-2022-0148463 filed on Nov. 9, 2022, the entire contents of which are incorporated herein by reference.

### FIELD OF THE INVENTION

The present disclosure relates to a flexible thermoelectric device module and a manufacturing method therefor and, more particularly, to a flexible thermoelectric device module, which is an energy conversion device that utilizes the voltage generated due to the temperature difference between both ends of a thermoelectric device to improve heat-to-electricity conversion efficiency while ensuring flexibility and mechanical safety, and a manufacturing method for the module.

### BACKGROUND OF THE INVENTION

Thermoelectric generators are devices used in energy harvesting that converts thermal energy into electrical energy. Their application range is gradually expanding with the recent development of flexible thermoelectric devices (TEDs) with soft and flexible structures, moving away from the initial structures that make existing thermoelectric devices difficult to deform because the existing thermoelectric devices are made of hard metal-based electrodes and semiconductors.

Conventional flexible thermoelectric (TE) modules can be largely divided into thin-film and bulk types. Thin-film modules have advantages in terms of flexibility and processability, but have the problem that a lower temperature difference occurs due to limitations in increasing thickness, which ultimately leads to a decrease in thermoelectric performance.

Meanwhile, bulk thermoelectric modules use solid bulk legs as thermoelectric semiconductor materials, and thus flexibility should be come from substrates, electrodes, etc.

FIG. 1 is a view showing the structure of a typical thermoelectric device module, and FIG. 2 is a view showing the characteristics required for components of a conventional thermoelectric device module and the types of materials applied thereto.

Referring to FIGS. 1 and 2, a thermoelectric device module according to conventional technology is manufactured by arranging thermoelectric legs composed of n-type and p-type semiconductors on a flexible substrate to secure flexibility, connecting an electrode for electrical connection of the thermoelectric legs, and filling the substrate with a filler material.

In addition, in the case of bulk flexible thermoelectric devices according to conventional technology, one side of the module is made of a flexible substrate such as polyimide, a liquid metal with elasticity such as copper strip or gallium-indium alloy (Eutectic Ga—In) is used as an electrode, and flexible materials with relatively high thermal conductivity such as PDMS, Ecoflex, fibers, and urethane foam are used as fillers. (Example: PDMS (0.16 Wm−1K−1), Ecoflex (0.2 Wm−1K−1))

Meanwhile, with the spread of wearable devices recently, the development of flexible thermoelectric devices that utilize low-temperature heat sources (below 100° C.) such as body heat is actively being carried out. However, in the conventional technology described above, low temperature differences occur due to internal heat loss of the device, which deteriorates the performance of the device and module.

### SUMMARY OF THE INVENTION

The present disclosure is intended to solve the above problems occurring in the related art. An objective of the present disclosure is to provide a flexible thermoelectric device that provides excellent heat-to-electricity conversion efficiency based on low thermal conductivity while ensuring flexibility and mechanical stability.

An objective of the present disclosure is to provide a flexible thermoelectric device that effectively secures a large temperature difference by applying a metastructure that includes a partial air gap as a filler to more tightly adhere to a low-temperature heat source such as the human body.

An objective of the present disclosure is to provide a manufacturing method for the flexible thermoelectric device based on a thermal circuit approach.

A flexible thermoelectric device module according to the present disclosure includes: at least one or more n-type and p-type thermal legs; a conductor for electrically connecting the thermoelectric legs; and an insulation means surrounding the thermoelectric legs, wherein the insulation means may be formed with an insulating resin-based material to include a partial air gap.

The insulation means may be formed of a metastructure having a negative Poisson's ratio or zero Poisson's ratio.

The insulation means may be a metastructure having any one of a stretchable pattern, a fractal pattern, and an auxetic pattern.

The insulation means may be further provided with a pod to supplement the support structure, wherein the pod may be formed with a wider cross-sectional area as going from a hot side to a cold side.

The pod may be an inverted triangle shape with an apex thereof facing the hot side.

The pod may protrude from an edge of a partial air gap formed in a metastructure.

Two or more but not more than four pods may be provided.

A manufacturing method for a thermoelectric device module according to the present disclosure may include: arranging multiple N-type and P-type thermoelectric legs on a flexible substrate; electrode connecting in which the arranged thermoelectric legs are electrically connected; and preparing a filler in which the filler is provided to surround the thermoelectric legs, wherein in the step of preparing the filler, a metastructure formed with a resin-based material to include a partial air gap may be provided to surround the multiple thermoelectric legs.

According to another aspect of the present disclosure, a manufacturing method for a flexible thermoelectric device module may include: forming multiple N-type and P-type thermoelectric legs and preparing upper and lower electrode sheets using a water-soluble bonding member in consideration of a connection structure between the thermoelectric legs; connecting a lower electrode in which the lower electrode sheet and lower ends of the thermoelectric legs are joined; mounting an insulation means in which the insulation means of a metastructure formed with a resin-based material to include a partial air gap is mounted on the thermoelectric legs to which the lower electrode is connected; connecting an upper electrode in which the upper electrode sheet is bonded to upper ends of the thermoelectric legs with the insulation means mounted; washing for removing the water-soluble bonding member constituting the upper electrode sheet and the lower electrode sheet; and substrate bonding in which a flexible substrate is bonded to the upper and lower electrodes exposed through the step of washing, wherein in the step of mounting the insulation means, depending on a required thermal performance, a mounting location of the insulation means may be selected from centers of the thermoelectric legs or a location adjacent to a cold side.

The insulation means mounted in the step of mounting the insulation means may be manufactured through a process in which a range of relative thermal resistance (γ) to air that can maintain a total conduction thermal resistance (Rcond) including a leg array at a set leg length is established, and an area fraction and thickness for maintaining the established γ range are determined to design the partial air gap.

According to a flexible thermoelectric device module of the present disclosure, by applying an insulation means of a metastructure pattern including a partial air gap as a filler covering a thermoelectric leg, it is possible to secure flexibility and mechanical stability and provide excellent heat-to-electricity conversion efficiency based on low thermal conductivity.

In addition, by applying the insulation means as described above, it is possible to provide improved energy harvesting performance by effectively securing a large temperature difference by more tightly adhering to a low-temperature heat source such as the human body.

### BRIEF DESCRIPTION OF THE DRAWINGS

FIG. 1 is a view showing the structure of a typical thermoelectric device module.

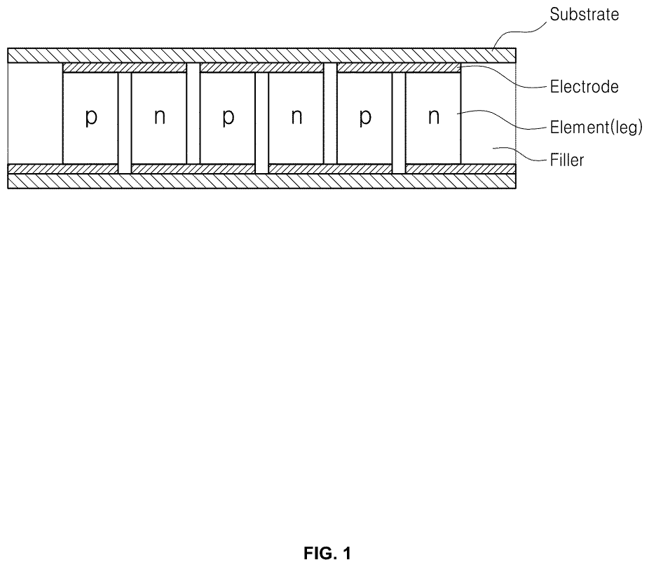

FIG. 2 is a view showing the characteristics required for components of a conventional thermoelectric device module and the types of materials applied thereto.

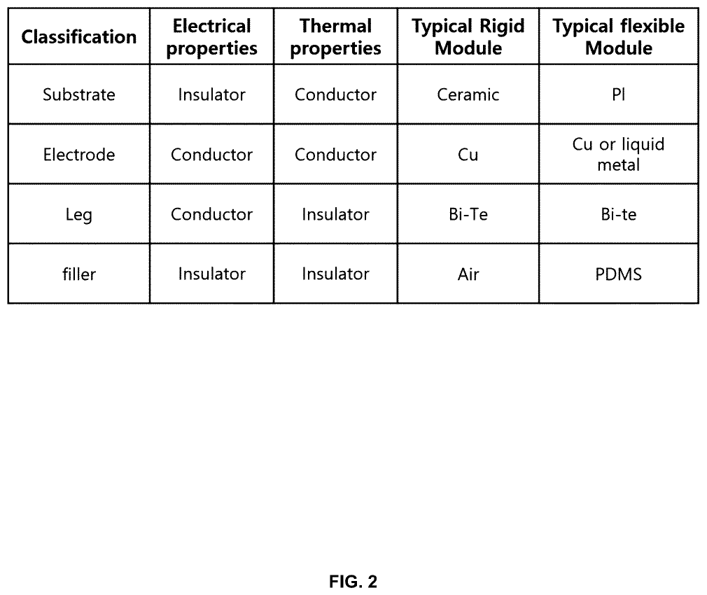

FIG. 3 is a view schematically showing an exemplary structure of a flexible thermoelectric device module according to the present disclosure.

FIG. 4 is a view showing the basic structure of a metastructure pattern applied to an insulation means, which is a key component of the present disclosure.

FIGS. 5A, 5B, 5C are views showing various examples of a metastructure pattern applied to an insulation means, which is a key component of the present disclosure.

FIGS. 6A, 6B are views showing various application forms of a pod for reinforcing support strength as another embodiment of an insulation means according to the present disclosure.

FIGS. 7A, 7B, 7C are views showing various application examples of a pod according to the arrangement position of an insulation means according to the present disclosure.

FIG. 8 is a view comparing the temperature difference ΔT between a high temperature part and a low temperature part according to the pattern structure of an insulation means according to the present disclosure, the pod configuration, and the number of pods.

FIG. 9 is a photograph of the Examples and Comparative Examples shown in FIG. 8.

FIGS. 10A and 10B are views comparing the temperature difference ΔT measurement results of Examples 1 to 6 shown in FIGS. 8 and 9.

FIG. 11A is a view comparing the temperature difference ΔT measurement results according to the leg length of each pattern type of an insulation means according to the present disclosure, and FIG. 11B is a view comparing the temperature difference ΔT measurement results according to the leg length with Comparative Examples 1 and 2 shown in FIGS. 8 and 9.

FIGS. 12A, 12B show a design process of a partial air gap of an insulation means according to the present disclosure based on a thermal circuit approach.

FIG. 13 is a graph showing the relative thermal resistance distribution of the filled structure.

FIG. 14 is a graph showing the area fill factor of legs.

FIG. 15 shows an example of a configuration of a thermoelectric performance evaluation system according to the length of a thermoelectric leg of a flexible thermoelectric device module according to the present disclosure.

FIG. 16 shows the results of measuring thermoelectric performance according to the length of a thermoelectric leg using the evaluation system shown in FIG. 15.

FIG. 17 is a graph comparing thermoelectric characteristics according to the measurement results of FIG. 16.

FIG. 18 shows a manufacturing process of a flexible thermoelectric device according to the present disclosure.

FIG. 19 shows an example of a flexible thermoelectric device module according to the present disclosure applied to flat and curved surfaces.

### DETAILED DESCRIPTION OF THE INVENTION

Hereinafter, some embodiments of the present disclosure will be described in detail through exemplary drawings.

When adding reference numerals to components of each drawing, identical components are described with the same numerals as much as possible even if they are shown on different drawings.

In addition, in describing the embodiments, if it is determined that a specific description of well-known functions or constructions hinders the understanding of the embodiments of the present disclosure, the description thereof is simplified or omitted. When a component is described as being “provided on”, “installed on”, or “connected to”, another component, it should be understood that the component can be directly provided on, installed on, or connected to that another component, but that other components may also be “provided”, “installed”, or “connected” between the components.

In general, the output of a thermoelectric device has the following relationship (Formula 1):

$$P ∝ Δ {T}^{2} \qquad ( Formula 1 )$$

(In this case, P is the heat flow, and ΔT is the temperature difference between hot and cold sides)

Thus, a flexible thermoelectric device module according to the present disclosure is characterized in that the module is installed between a hot side and a cold side and utilizes air (0.025 Wm⁻¹K⁻¹) as an insulating configuration while ensuring flexibility and mechanical stability based on a dynamic metastructure pattern.

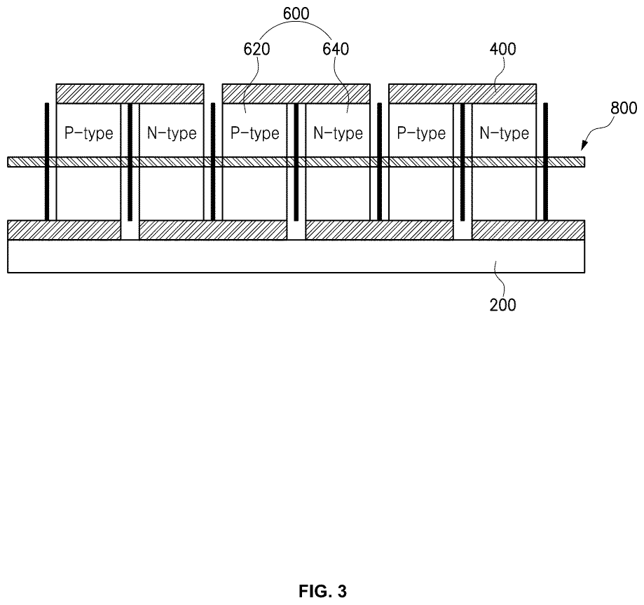

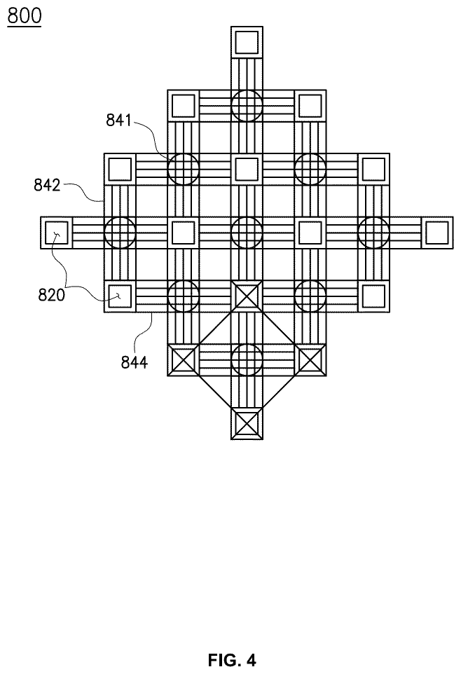

To be specific, FIG. 3 is a view schematically showing an exemplary structure of a flexible thermoelectric device module according to the present disclosure, and FIG. 4 is a view showing the basic structure of a metastructure pattern applied to an insulation means, which is a key component of the present disclosure.

Referring to FIGS. 3 and 4, the flexible thermoelectric device module according to the present disclosure includes a conductor 400 for electrically connecting a plurality of thermoelectric legs 600 provided on a flexible substrate 200, and in order to secure the temperature difference ΔT of the thermoelectric legs 600, an insulation means 800 including a partial air gap 820 is provided to surround the thermoelectric legs 600.

That is, on the upper side of the flexible substrate 200, at least one p-type thermoelectric leg 620 and one n-type thermoelectric leg 640 are connected by the conductor 400 to form a thermoelectric circuit, and the thermoelectric legs are surrounded by the insulation means 800 to form an insulating structure between a hot side and a cold side.

In addition, the insulation means 800 is formed with an insulating resin-based material to include the partial air gap 820, unlike a conventional filler that completely encloses the entire thermoelectric leg without any gaps, so that an insulating effect by an air gap may be secured.

That is, in the flexible thermoelectric device module according to the present disclosure, the insulation means 800 is formed to have a metastructure pattern, including a portion formed of an insulating resin-based material and a portion formed of an air gap. The metastructure pattern has a Poisson's ratio close to zero or a negative Poisson's ratio, which enables the device to maintain bending deformation or support strength as well as effective insulation performance to be ensured by maintaining an air gap.

As an example, referring to the insulation means 800 shown in FIG. 4, the metastructure pattern is formed by first direction rods 842 and second direction rods 844 formed in parallel lines intersecting each other to form multiple nodes 841, and the multiple nodes 841 are formed as partial air gaps 820 at the next intersection points connected by the first and second direction rods 842 and 844.

That is, in the present embodiment, the insulation means 800 is formed such that a plurality of intersections formed by the first and second directional rods 842 and 844 alternately form the partial air gaps 820 and nodes 842, thereby creating an overall lattice-shaped metastructure pattern.

The insulation means 800 formed as described above is arranged in a parallel manner between the hot side and the cold side to establish a support structure while wrapping the thermoelectric legs 600, thereby facilitating elastic deformation, ensuring effective adhesion even to random curves, and forming an insulating structure utilizing the partial air gaps 820.

Meanwhile, the insulation means 800 having the above function may be formed to have various types of metastructure patterns.

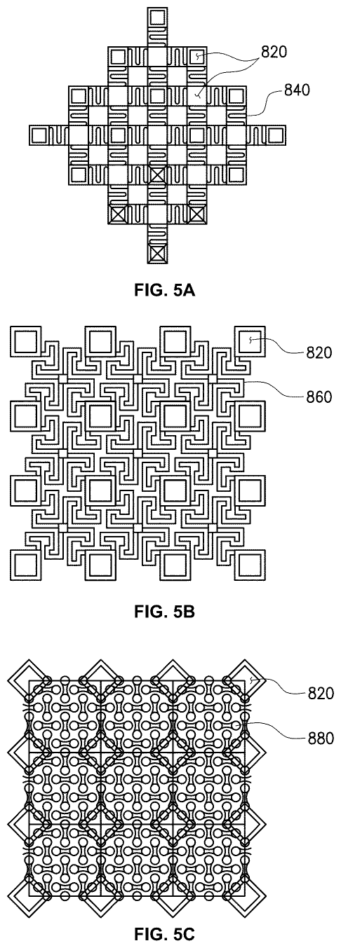

FIG. 5 is a view showing various examples of a metastructure pattern applied to the insulation means, which is a key component of the present disclosure.

FIG. 5A shows that the metastructure is formed in a lattice shape including a stretch pattern 840 and exhibits a zero Poisson's ratio, and the node portion is formed as the partial air gap 820, and FIG. 5B shows that the metastructure with zero Poisson's ratio is formed by including partial air gap 820 at regular intervals in a fractal pattern 860 with self-similarity and circularity.

In addition, FIG. 5C shows that the metastructure with a negative Poisson's ratio is formed by creating partial air gaps 820 at regular intervals with an auxetic pattern 880.

That is, the insulation means 800 according to the present disclosure may be designed in a shape pattern by determining the range of formation of the partial air gap 820 based on a thermal circuit approach while the ratio of strain in the direction of a tensile force to the strain in the perpendicular direction has a “value close to 0” or a “negative value (−).”

Meanwhile, the insulation means 800 formed as described above may further include a pod for reinforcement of support strength.

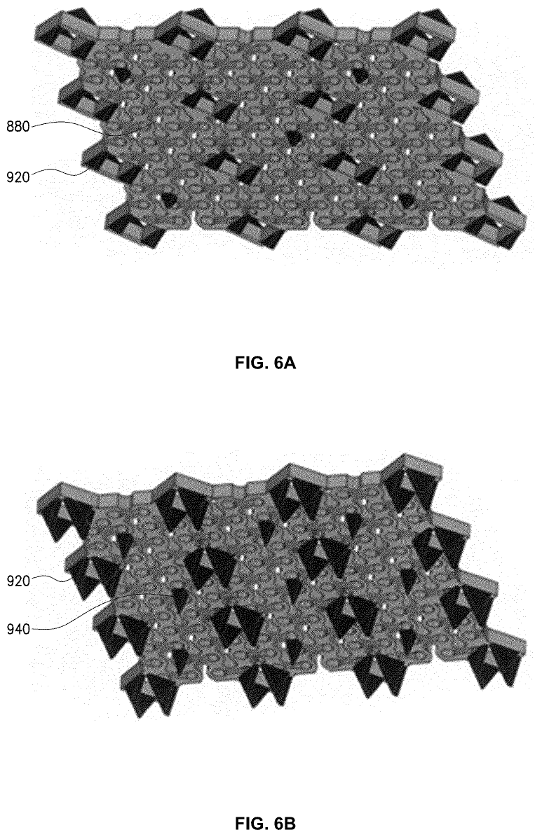

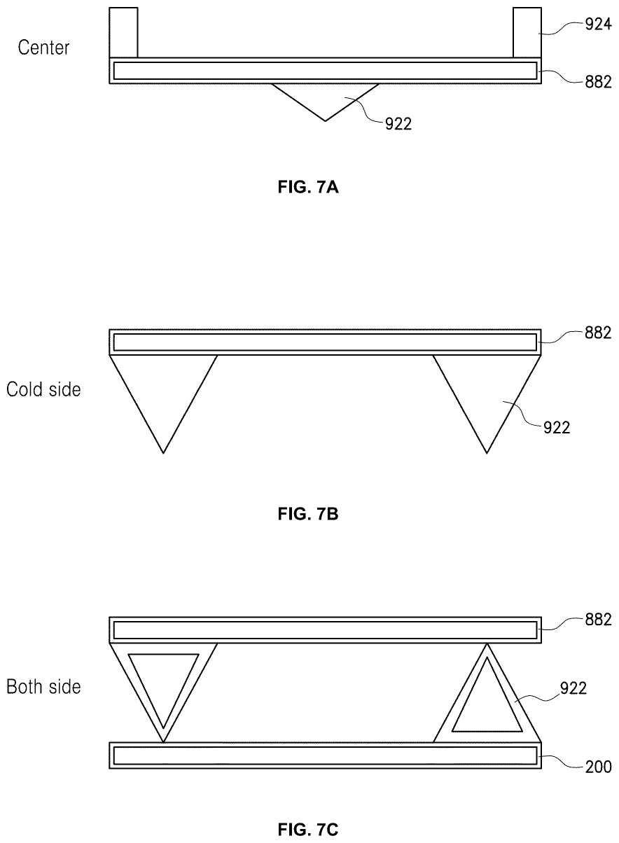

FIG. 6 is a view showing various application forms of a pod for reinforcing support strength as another embodiment of the insulation means according to the present disclosure, and FIG. 7 is a view showing various application examples of a pod according to the arrangement position of the insulation means according to the present disclosure.

Referring to FIGS. 6 and 7, the present embodiment is an embodiment including the auxetic pattern 880, in which a pod 920 is provided to protrude along the edge of the partial air gap to form an air gap.

That is, the pod 920 is a protruding structure formed on the hot side and the cold side centered on the thermoelectric leg 600 to enable distributed support resisting external force.

In addition, the pod 920 may be added as a sub-pod 940 as shown in FIG. 6B to a pattern area other than the edge of the partial air gap if necessary to increase the support strength.

In addition, the pod 920 may be formed to protrude upward and/or downward from a pattern layer 922 depending on the arrangement position of the insulation means 800 as shown in FIG. 7.

To be specific, the pod 920 may be divided into a hot side pod 922 that protrudes toward the hot side and a cold side pod 924 that protrudes toward the v centered on the pattern layer 922, and may be selectively applied depending on the arrangement position of the pattern layer 922.

That is, when the pattern layer 922 is placed in the center of the thermoelectric leg 600 as shown in FIG. 7A, the hot side pod 922 and the cold side pod 924 may be formed to protrude in different directions.

In addition, when the pattern layer 922 is placed adjacent to the cold side as in FIG. 7B, only the hot side pod 922 may be formed to protrude to reinforce the support strength.

Meanwhile, the pod 920 formed to protrude to support the dispersion of external force may reduce the temperature difference ΔT between the hot side and the cold side by forming a heat transfer path having a higher thermal conductivity than air.

Thus, the pod 920 may be formed into a truss structure as in FIG. 7C so that the support strength may be reinforced while reducing the amount of input heat transferred through the pod 920.

In addition, from the above perspective, the pod 920 may be formed with a wider cross-sectional area as the pod 920 moves from the hot side to the cold side, thereby minimizing the amount of heat input.

As an example, the pod 920 according to the present disclosure may be formed in an inverted triangular shape with the apex facing the hot side.

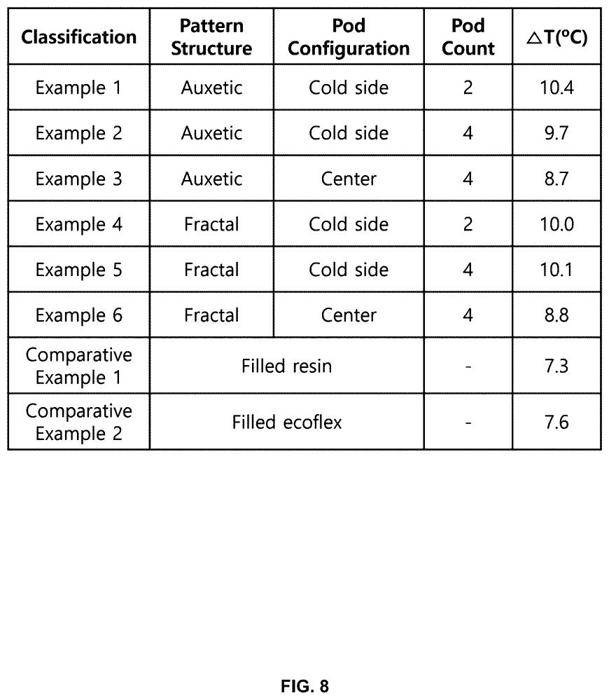

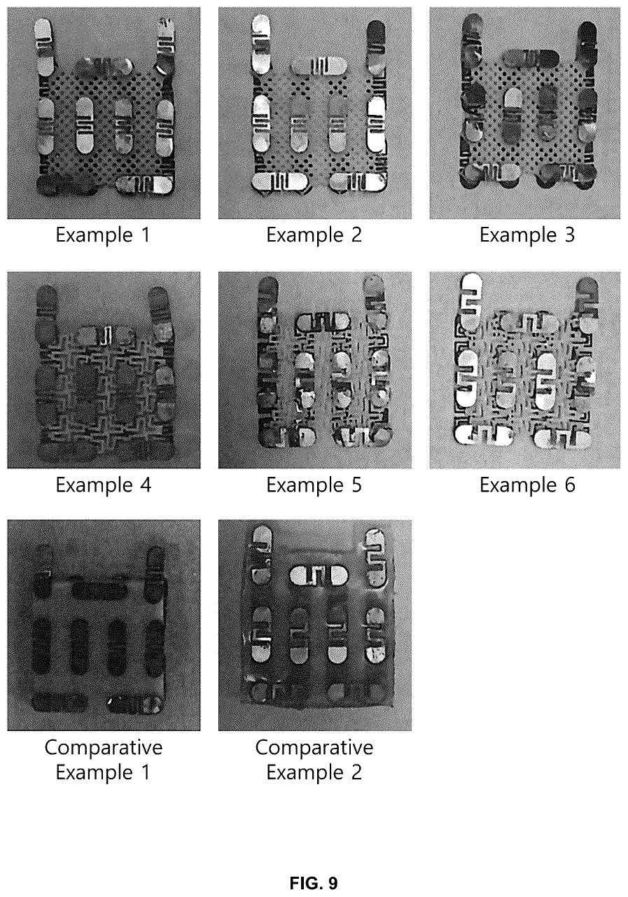

Meanwhile, FIG. 8 is a view comparing the temperature difference ΔT between a high temperature part and a low temperature part according to the pattern structure of the insulation means according to the present disclosure, the pod configuration, and the number of pods, and FIG. 9 is a photograph of the Examples and Comparative Examples shown in FIG. 8.

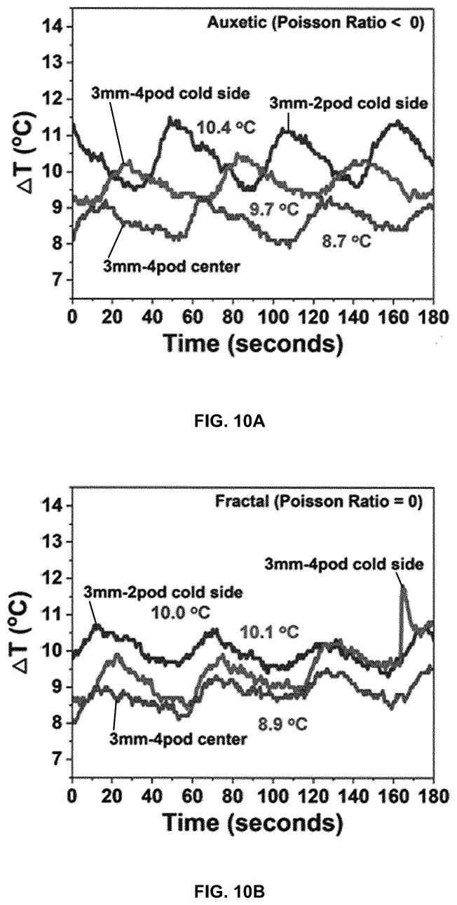

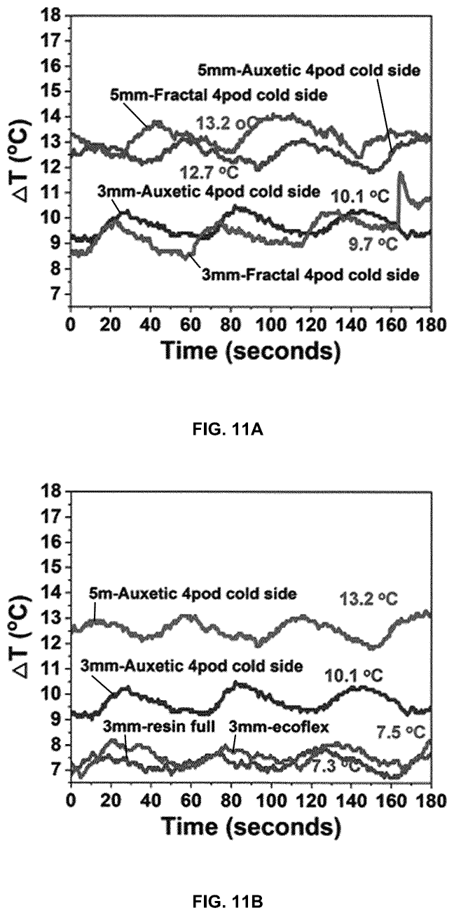

In addition, FIG. 10 is a view comparing the temperature difference ΔT measurement results of Examples 1 to 6 shown in FIGS. 8 and 9, and FIG. 11A is a view comparing the temperature difference ΔT measurement results according to the leg length of each pattern type of an insulation means according to the present disclosure, whereas FIG. 11B is a view comparing the temperature difference ΔT measurement results according to the leg length with Comparative Examples 1 and 2 shown in FIGS. 8 and 9.

Referring to FIGS. 8 to 11, Example 1 exhibits a negative Poisson's ratio due to an auxetic pattern, is installed adjacent to the cold side, and has two pods 920, and Example 2 has the same shape as Example 1 with two more pods 920 added.

When examining the temperature difference ΔT measurement results between the hot side and the cold side according to the above two types of examples, it can be confirmed that the temperature difference ΔT measurement value of Example 1, which has a smaller number of pods 920 in the same structure, is higher than that of Example 2 as shown in FIG. 10A.

In addition, Example 3 has the same structure as Example 2, but the installation location of the insulation means 800 is positioned centrally, and a lower temperature difference ΔT measurement value is confirmed than in Example 2.

Meanwhile, Example 4 exhibits a zero Poisson's ratio due to a fractal pattern, is installed adjacent to the cold side, and has two pods 920, and Example 5 has the same shape as Example 4 with two more pods 920 added.

When examining the temperature difference ΔT measurement results between the hot side and the cold side according to the above two types of examples, it can be confirmed that the temperature difference ΔT measurement value was slightly higher in Example 5, where two more pods were added 2 as shown in FIG. 10B.

In addition, Example 6 has the same structure as Example 5, but the installation location of the insulation means 800 is positioned centrally, and a lower temperature difference ΔT value was confirmed than Example 5 as well as Example 4.

That is, the insulation means 800 according to the present disclosure may be provided in a form that allows selective application of a metastructure pattern and pod 920 having a partial air gap 820 and a zero Poisson's ratio or a negative Poisson's ratio, and regardless of the shape of the metastructure pattern, the highest temperature difference ΔT may be secured when the position of the insulation means 800 is positioned adjacent to the cold side.

Meanwhile, as shown in FIG. 11, when the same pattern type and the same number of pods 920 are used, the temperature difference ΔT was higher in the structure in which the length of the legs is formed relatively longer.

In addition, since Comparative Example 1, in which the space between the thermocouple legs is filled with resin, and Comparative Example 2, in which the space is filled with Ecoflex, show relatively lower temperature difference ΔT values than many examples according to the present disclosure, regardless of the arrangement location, the number of pods, and the shape of the metastructure pattern, it was found that the insulation means 800 of the present disclosure including the partial air gaps 820 and metastructure patterns had a higher temperature difference ΔT value than the structures filled with fillers as in Comparative Examples 1 and 2.

In addition, in cases where the same metastructure pattern and number of pods are present, placing the insulation means 800 adjacent to the cold side may secure a higher temperature difference ΔT, and in the case of the auxetic metastructure pattern, it is confirmed that a structure with a smaller number of pods 920 may secure a higher temperature difference ΔT.

Meanwhile, the insulation means 800 according to the present disclosure may further improve the effect of the above-mentioned features by designing the area occupied by the partial air gap 820 in the entire area.

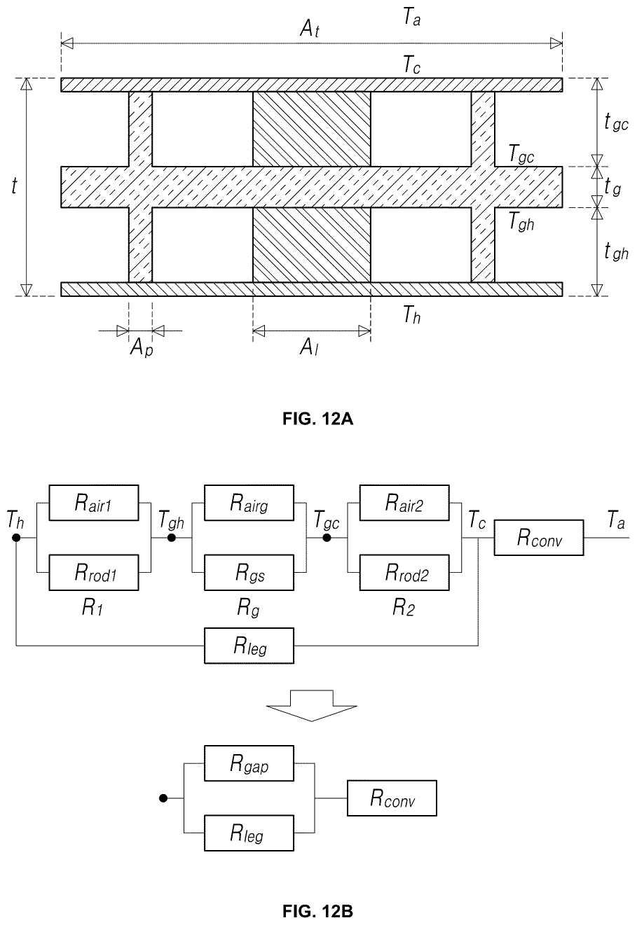

FIG. 12 shows a design process of the partial air gap of the insulation means according to the present disclosure based on a thermal circuit approach.

FIG. 12A is a schematic view of the insulation means 800 according to the present disclosure. The thermal circuit approach is based on the assumption that 1. the parts defined as nodes in the thermal circuit have the same temperature, 2. they are interpreted as small geometric structures, and 3. they are in stationary states (time-independent).

Based on the above assumptions, the thermal resistance of the partial air gap (Rgap) may be expressed as in FIG. 12B and below (Formula 2).

$${R}_{gap} = {R}_{1} + {R}_{g} + {R}_{2} = {( 1 / {R}_{air 1} + 1 / {R}_{rod 1} )}^{- 1} + {( 1 / {R}_{a i r g} + 1 / {R}_{g s} )}^{- 1} + {( 1 / {R}_{air 1} + 1 / {R}_{rod 1} )}^{- 1} \qquad ( Formula 2 )$$

In addition, when considering only conduction within the air gap, the resistance R may be expressed as (Formula 3).

$$R = t / A σ \qquad ( Formula 3 )$$

(where A is the area, t is the thickness, and σ is the thermal conductivity)

Meanwhile, in the above geometric structure, the relationship between a porosity p of the insulation means 800 and the area d may be expressed as the area ratio of the entire air gap and the pod as in (Formula 4), and ratio of thermal conductivity a of the insulation means 800 to that of air may be expressed as in (Formula 5), and the thickness ratio Ig of each layer may be expressed as in (Formula 6).

$$d = {A}_{p} / ( {A}_{t} - {A}_{l} ) \qquad ( Formula 4 )$$

$$a = {σ}_{g} / {σ}_{a i r} \qquad ( Formula 5 )$$

$${l}_{g} = {t}_{g} / t \qquad ( Formula 6 )$$

(where Aₚ is the pod area, Aₜ is the total area, Aᵢ is the area of the thermoelectric leg, σ_{g} is the thermal conductivity of the insulation means, σₐᵢᵣ is the thermal conductivity of air, and t_{g} is the thickness of the insulation means)

In addition, the thermal resistance (R_{gap}) of the partial air gap is again expressed as (Formula 7), and assuming that the cold side area (d_{gh}) and the hot side area (d_{ch}) are equal to “d”, the cold side thickness ratio (I_{gh}) and the hot side thickness ratio (I_{ch}) are equal to “I”, and a is 10, the relative thermal resistance γ to air and the area d may be expressed as (Formula 8).

$$Rgap = \frac{t}{{σ}_{air} {A}_{air}} ( \frac{{l}_{gh}}{( 1 - {d}_{gh} ) + {a}_{gh}} + \frac{t}{( 1 - p ) a - p} + \frac{{l}_{gc}}{( 1 - {d}_{gc} ) + {ad}_{gc}} ) = {R}_{air} γ \qquad ( Formula 7 )$$

$$γ = ( \frac{2 l}{1 + 9 d} + \frac{{l}_{g}}{10 - 9 p} ) \qquad ( Formula 8 )$$

Meanwhile, the total conduction thermal resistance Rcond including the air gap and the leg array may be expressed as (Formula 9) when the fill factor of the leg area is F.

$${R}_{cond} = {( \frac{1}{{R}_{gap}} + \frac{1}{{R}_{leg}} )}^{- 1} = \frac{t}{A} ( \frac{1}{( 1 - F ) \frac{{σ}_{air}}{γ} + F {σ}_{leg}} ) \qquad ( Formula 9 )$$

In addition, the relative thermal resistance (Rᵣₑₗ) for a filled structure shows the following distribution between the area fill factor and the relative thermal resistance to air (Rₐᵢᵣ/R_{gap}, γ).

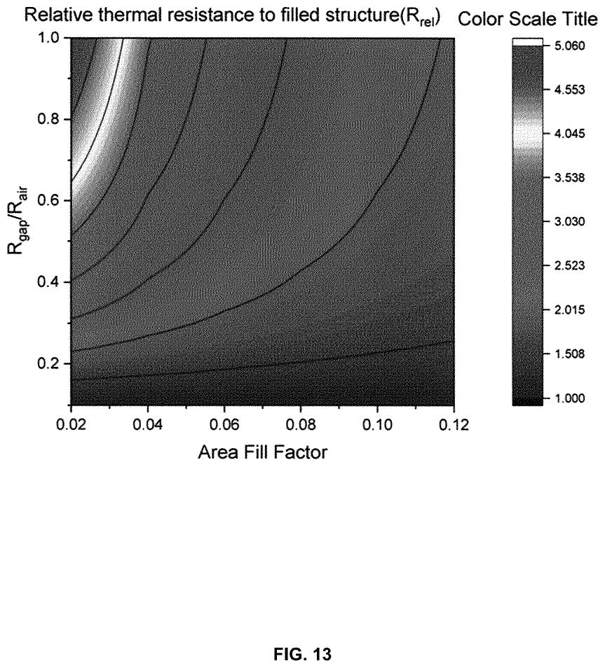

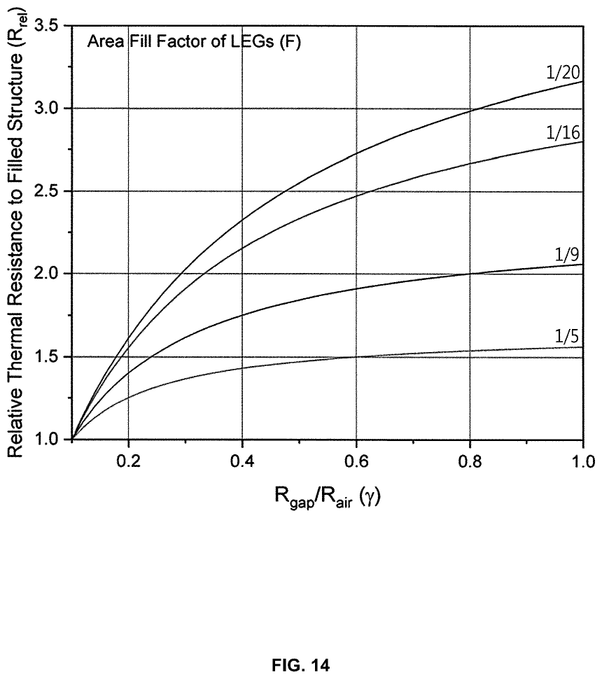

FIG. 13 is a graph showing the relative thermal resistance distribution of the filled structure, and FIG. 14 is a graph showing the area fill factor of legs.

Referring to the graphs in FIGS. 13 and 14, in designing partial air gaps using thermal resistance analysis, first of all, when the area fill factor is less than 0.12 and the relative thermal resistance γ to air is greater than 0.6, it is shown that the thermal resistance due to conduction is more than twice that of the conventional filled structure, and when the fill factor is maintained at 1/16 and γ is 0.4 or more, it is shown that sufficient thermal resistance may be obtained.

However, as the thermal resistance decreases when γ is less than 0.4 with the fill factor of 1/16 or less, when γ is maintained above 0.5 or more with the fill factor of approximately 0.1 to 0.05, thermal resistance performance similar to that of an air gap may be provided.

Thus, the design of the partial air gaps may be achieved by setting the length of the leg within the above range, establishing a range of the relative thermal resistance (γ) to air that can maintain the total conduction thermal resistance (Rcond) including the leg array at the set leg length, and determining the area fraction and thickness to maintain the set γ range.

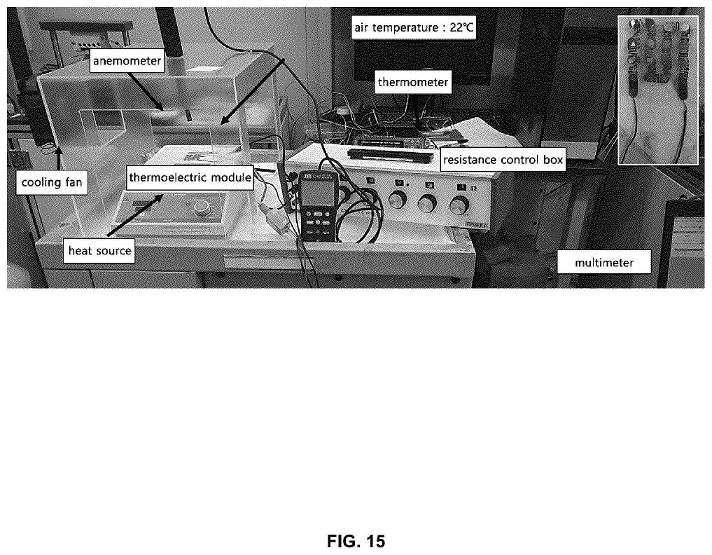

Meanwhile, to verify the thermoelectric performance of the flexible thermoelectric device module according to the present disclosure, an energy harvesting thermoelectric measurement setup was configured as shown in FIG. 15, and thermoelectric performance evaluation was performed under natural cooling conditions.

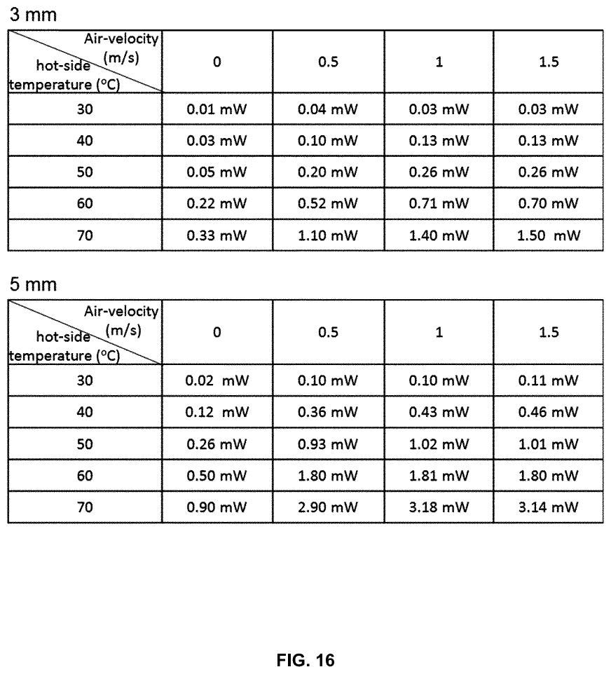

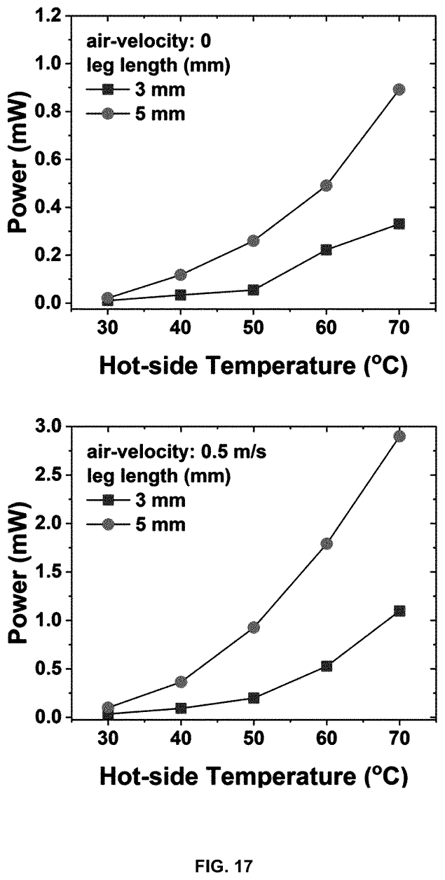

To be specific, FIG. 15 shows an example of a configuration of a thermoelectric performance evaluation system according to the length of a thermoelectric leg of the flexible thermoelectric device module according to the present disclosure, FIG. 16 shows the results of measuring thermoelectric performance according to the length of a thermoelectric leg using the evaluation system shown in FIG. 15, and FIG. 17 is a graph comparing thermoelectric characteristics according to the measurement results of FIG. 16.

When examining the results of the thermoelectric performance evaluation with reference to FIGS. 15 to 17, first, the thermoelectric performance measurement setup is configured to create a windy environment using a cooling fan with the ambient temperature set to 22° C., and to control the temperature of the hot side using a heat plate. In addition, the performance evaluation was conducted while the temperature of the hot side was controlled in the range of 30° C. to 70° C. and the air velocity was controlled in the range of 0 m/s to 1.5 m/s.

The lengths of the thermoelectric legs were 3 mm and 5 mm, and the load resistances were set to 0.4Ω and 1.1Ω, respectively, and the measurement results were confirmed using a measurement table as in FIG. 16.

To be specific, the output power values were measured by configuring 3 mm and 5 mm long thermoelectric legs and controlling the hot side temperature in the range of 30° C. to 70° C., and the output measurement values were measured by additionally adjusting the air velocity from 0 m/s to 1.5 m/s using the cooling fan, resulting in output graphs as in FIG. 17.

Referring to the graphs, it was confirmed that the output power values increased for both 3 mm and 5 mm leg lengths as the temperature of the hot side increased, and the increase rate was higher for the 5 mm thermoelectric leg than for the 3 mm thermoelectric leg. This was shown to be a result of the increase in temperature difference between the hot side and the cold side as the length of the thermoelectric leg increased, and similarly, it was shown that the thermoelectric performance was improved when the air velocity was increased by operating the cooling fan.

In addition, the flexible thermoelectric device module of the present disclosure exhibited a higher power output value when applied to the 5 mm thermoelectric leg than when applied to the 3 mm thermoelectric leg.

The above measurement results confirm that the proportion of partial air gaps increases as the leg length increases, resulting in a high temperature difference as the partial air gaps are designed by establishing a range of the relative thermal resistance (γ) to air that can maintain the total conduction thermal resistance (Rcond) including the leg array at a set leg length, and determining the area fraction and thickness to maintain the set γ range.

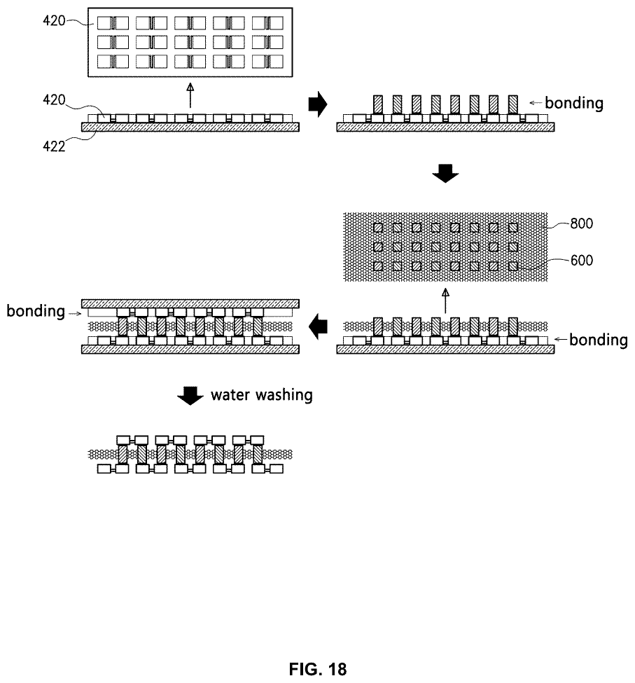

Meanwhile, FIG. 18 shows a manufacturing process of the flexible thermoelectric device according to the present disclosure.

The insulation means 800 designed with partial air gaps as described above is manufactured into the flexible thermoelectric device module through the following process.

First, in a manufacturing method for the flexible thermoelectric device module according to the present disclosure, a step of manufacturing an electrode sheet is performed considering the upper and lower connection structures of the thermoelectric leg 600.

To be specific, in the step of manufacturing an electrode sheet, a cutting electrode 420 is prepared for the upper connection of the thermoelectric leg 600, and the prepared cutting electrode 420 is placed on a water-soluble bonding member to form an upper electrode sheet, and in a similar manner, by preparing a lower electrode sheet for lower connection of the thermoelectric legs 600, an electrode sheet for electrically connecting the upper and lower parts of a plurality of thermoelectric legs 600 is provided.

In addition, when the step of manufacturing an electrode sheet as described above is completed, a lower electrode connection step of joining the lower electrode sheet and the thermoelectric leg 600 is performed.

In the lower electrode connection step, the lower end of the thermoelectric leg 600 and the cutting electrode 420 provided on the lower electrode sheet are connected through soldering, and when the lower electrode connection step is completed, an insulation means mounting step is performed to mount the insulation means 800 on the joined thermoelectric leg 600.

In the insulation means mounting step, the insulation means 800 manufactured based on the above-mentioned partial air gap 820 design may be fitted to correspond to the thermoelectric leg 600, and the placement location of the insulation means 800 may be selected between the central portion and the area adjacent to the cold side as needed.

Meanwhile, when the insulation means mounting step is completed as described above, an upper electrode connection step of joining the upper electrode sheet to the upper end of the thermoelectric leg 600 is performed.

In the upper electrode connection step, the manufactured upper electrode sheet is positioned so as to correspond to the upper end of the thermoelectric leg 600, and then joined through soldering.

In addition, when the upper electrode connection step is completed as described above, a washing step is performed to remove the water-soluble bonding member 422 that constitutes the upper and lower electrode sheets.

That is, when an assembly in which the upper electrode sheet and the lower electrode sheet are connected are washed with water through the above washing step to remove the bonding member 422, a thermoelectric element may be manufactured in which the upper and lower ends of the thermoelectric element 600 are electrically connected to each other, with the thermoelectric legs 600 wrapped by the insulation means 800.

In addition, by combining the thermoelectric element manufactured as described above with the flexible substrate 200, the manufacture of the flexible thermoelectric device module is completed.

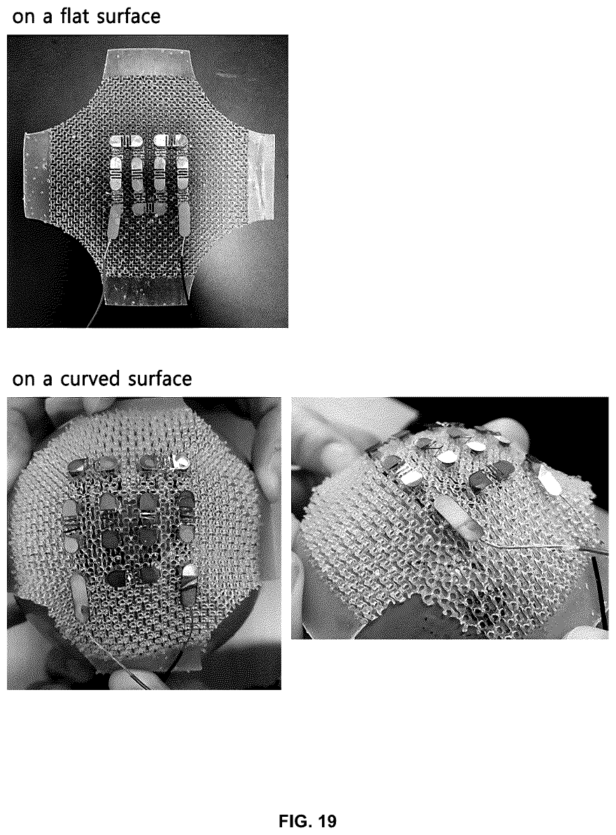

FIG. 19 shows an example of the flexible thermoelectric device module according to the present disclosure applied to flat and curved surfaces.

The flexible thermoelectric device module manufactured as described above is configured in a form in which the thermoelectric legs 600 are wrapped by the insulation means 800 having partial air gaps 820, so that insulation between the hot side and the cold side is achieved by an air layer, and since mechanical flexibility and support strength are secured by the metastructure pattern, the module may be easily attached to not only flat surfaces and curved surfaces with a certain curvature, but also to unspecified curved surfaces such as the human body.

Therefore, when the flexible thermoelectric device module according to the present disclosure is applied to a wearable device, a more stable power supply may be achieved.

According to the flexible thermoelectric device module of the present disclosure, by applying an insulation means of a metastructure pattern including a partial air gap as a filler covering a thermoelectric leg, it is possible to secure flexibility and mechanical stability and provide excellent heat-to-electricity conversion efficiency based on low thermal conductivity.

Furthermore, by applying the insulation means of the metastructure pattern as described above, it is possible to effectively secure a large temperature difference by more tightly adhering to a low-temperature heat source such as the human body and to provide improved energy harvesting performance in various industrial fields since the energy harvesting module structure can be designed to fit the installation site.

In a situation where the need for carbon neutrality and efficient energy management are required from a policy perspective, it is expected that the flexible thermoelectric device module according to the present disclosure will be able to promote the growth of the energy harvesting market, and since the module can be applied in various industrial fields, the usability thereof is very high.

What is claimed is:

1. A thermoelectric device module, comprising:
at least one or more n-type and p-type thermal legs;
a conductor for electrically connecting the thermoelectric legs; and
an insulation means surrounding the thermoelectric legs,
wherein the insulation means is formed with an insulating resin-based material to include a partial air gap.

2. The module of claim 1, wherein the insulation means is formed of a metastructure having a negative Poisson's ratio or zero Poisson's ratio.

3. The module of claim 1, wherein the insulation means is a metastructure having any one of a stretchable pattern, a fractal pattern, and an auxetic pattern.

4. The module of claim 1, wherein the insulation means is further provided with a pod to supplement the support structure,
wherein the pod is formed with a wider cross-sectional area as going from a hot side to a cold side.

5. The module of claim 4, wherein the pod is an inverted triangle shape with an apex thereof facing the hot side.

6. The module of claim 4, wherein the pod protrudes from an edge of a partial air gap formed in a metastructure.

7. The module of claim 6, wherein two or more but not more than four pods are provided.

8. A manufacturing method for a thermoelectric device module, the method comprising:
arranging multiple N-type and P-type thermoelectric legs on a flexible substrate;
electrode connecting in which the arranged thermoelectric legs are electrically connected; and
preparing a filler in which the filler is provided to surround the thermoelectric legs,
wherein in the step of preparing the filler, a metastructure formed with a resin-based material to include a partial air gap is provided to surround the multiple thermoelectric legs.

9. A manufacturing method for a thermoelectric device module, the method comprising:
forming multiple N-type and P-type thermoelectric legs and preparing upper and lower electrode sheets using a water-soluble bonding member in consideration of a connection structure between the thermoelectric legs;
connecting a lower electrode in which the lower electrode sheet and lower ends of the thermoelectric legs are joined;
mounting an insulation means in which the insulation means of a metastructure formed with a resin-based material to include a partial air gap is mounted on the thermoelectric legs to which the lower electrode is connected;
connecting an upper electrode in which the upper electrode sheet is bonded to upper ends of the thermoelectric legs with the insulation means mounted;
washing for removing the water-soluble bonding member constituting the upper electrode sheet and the lower electrode sheet; and
substrate bonding in which a flexible substrate is bonded to the upper and lower electrodes exposed through the step of washing,
wherein in the step of mounting the insulation means, depending on a required thermal performance, a mounting location of the insulation means is selected from centers of the thermoelectric legs or a location adjacent to a cold side.

10. The method of claim 9, wherein the insulation means mounted in the step of mounting the insulation means is manufactured through a process in which a range of relative thermal resistance (γ) to air that can maintain a total conduction thermal resistance (R cond) including a leg array at a set leg length is established, and an area fraction and thickness for maintaining the established γ range are determined to design the partial air gap.
